(19) United States
(12) Patent Application Publication
(10) Pub. No.: US 2011/0076784 A1
(43) Pub. Date: Mar. 31, 2011

(54) Fabrication of Magnetic Element Arrays

(75) Inventors: David Druist, Santa Clara, CA (US); Vladimir Nikitin, Campbell, CA (US); Dmytro Apalkov, San Jose, CA (US)

(73) Assignee: GRANDIS INC., Milpitas, CA (US)

(21) Appl. No.: 12/569,851

(22) Filed: Sep. 29, 2009

(51) Int. Cl. H01L 21/28

(52) U.S. Cl. 438/3; 257/E21.158

(57) ABSTRACT

Techniques for fabricating an array of magnetic elements to form memory and other devices with a high areal density.

### BACKGROUND

This patent document relates to magnetic structures having at least one free ferromagnetic layer, including spin-torque magnetic random access memory (MRAM) cells, and fabrication of such MRAM cells.

Various magnetic materials use multilayer structures which have at least one ferromagnetic layer configured as a “free” layer whose magnetic direction can be changed by an external magnetic field or a control current. Magnetic memory devices may be constructed using such multilayer structures where information is stored based on the magnetic direction of the free layer.

One example for such a multilayer structure is a spin valve (SV) which includes at least three layers: two ferromagnetic layers and a conducting layer between the two ferromagnetic layers. Another example for such a multilayer structure is a magnetic or magnetoresistive tunnel junction (MTJ) which includes at least three layers: two ferromagnetic layers and a thin layer of a non-magnetic insulator as a barrier layer between the two ferromagnetic layers. The insulator for the middle barrier layer is not electrically conducting and hence functions as a barrier between the two ferromagnetic layers. However, when the thickness of the insulator is sufficiently thin, e.g., a few nanometers or less, electrons in the two ferromagnetic layers can “penetrate” through the thin layer of the insulator due to a tunneling effect under a bias voltage applied to the two ferromagnetic layers across the barrier layer.

Notably, the resistance to the electrical current across the MTJ or SV structures varies with the relative direction of the magnetizations in the two ferromagnetic layers. When the magnetizations of the two ferromagnetic layers are parallel to each other, the resistance across the MTJ or SV structures is at a minimum value RP. When the magnetizations of the two ferromagnetic layers are anti-parallel with each other, the resistance across the MTJ or SV is at a maximum value RAP. The magnitude of this effect is commonly characterized by the tunneling magnetoresistance (TMR) in MTJs or magnetoresistance (MR) in SVs defined as (R_{AP}−R_{P})/R_{P}.

### SUMMARY

This document discloses Techniques for fabricating an array of magnetic elements to form memory and other devices with a high areal density.

In one aspect, a double patterning process is provided to fabricate magnetic elements with at least one dimension that is less than the critical dimension of a patterning process used in the fabrication. For example, a method for fabricating a magnetic element array on a substrate is provided to include forming a base electrode layer on a substrate and magnetic element layers over the base electrode layer to include a fixed layer having a fixed layer magnetization, a free layer having a free layer magnetization that is changeable relative to the fixed layer magnetization based on a spin transfer torque, and a nonmagnetic spacer layer between the fixed layer and the free layer; applying a patterning process to form a template of parallel template stripes over the magnetic element layers with a spacing; forming a layer of a first masking material, that is electrically conductive, to cover top and side surfaces of the parallel template stripes and exposed surfaces of the magnetic element layers between the parallel template stripes; and patterning the layer of the first masking material to selectively remove the first masking material on top surfaces of the parallel template stripes and exposed surfaces of the magnetic element layers between the parallel template stripes while retaining the first masking material on side surfaces of the parallel template stripes. This method also includes removing the parallel template stripes while retaining the first masking material originally on side surfaces of the parallel template stripes to form a first template of parallel masking stripes that are located on top of the magnetic element layers and have a spacing less than a spacing between the parallel template stripes; using the first template of parallel masking stripes as a first mask over the magnetic element layers to selectively remove the magnetic element layers and the underlying base electrode on the substrate located between the parallel masking stripes while retaining the magnetic element layers and the underlying base electrode on the substrate at locations underneath the first template of parallel masking stripes; forming an interlayer dielectric layer over the substrate in which the retained magnetic element layers and the underlying base electrode on the substrate are embedded; and forming a second template of parallel masking stripes made of a second masking material on the interlayer dielectric layer that are perpendicular to the parallel masking stripes of the first template embedded in the interlayer dielectric layer. Next, this method uses the second template of parallel masking stripes as a second mask to selectively remove the interlayer dielectric layer, the first masking material, the magnetic element layers and the underlying base electrode on the substrate located between the parallel masking stripes of the second template to form islands of the interlayer dielectric layer, the first masking material, the magnetic element layers and the underlying base electrode as an array of magnetic elements on the substrate.

In another aspect, a magnetically permeable structure is formed to enhance magnetic stability of magnetic elements in an array.

These and other aspects and related implementations are described in greater detail in the drawings, the description and the claims.

### BRIEF DESCRIPTION OF THE DRAWINGS

FIG. 1A shows an example of a magnetic element in the form a spin valve.

FIG. 1B shows an example of a magnetic element in the form of a spin tunneling junction.

FIG. 2 shows an exemplary arrayed magnetic elements on a substrate.

FIG. 3 shows an example of a fabrication process for forming an array of magnetic elements on a substrate where each magnetic element has one dimension less than the critical dimension of a patterning process used in the fabrication.

FIGS. 4A through 4J shows an exemplary implementation of the fabrication process in FIG. 3.

FIGS. 5 and 6 show two examples for fabricating magnetically permeable structures on an array of magnetic elements to enhance the magnetic stability of the magnetic elements.

FIG. 7 shows a circuitry for a magnetic element based on spin-transfer torque switching.

FIG. 8 shows an exemplary circuit that operates an arrayed magnetic memory device based on spin-transfer torque switching.

### DETAILED DESCRIPTION

An array of magnetic elements such as MTJ or SV cells can be densely formed on a substrate to increase the number of magnetic elements in a given wafer area for high storage capacity applications. A smallest feature that can be formed in a layer is determined by the critical dimension of a patterning process such as a photolithography process that is used to pattern the layer. The fabrication techniques described in this document allow fabrication of the smallest dimension of magnetic elements in an array less than the critical dimension of the patterning process used for the fabrication to provide high density magnetic element arrays. The structures of examples of magnetic elements are provided below and are followed by fabrication techniques for fabricating such structures.

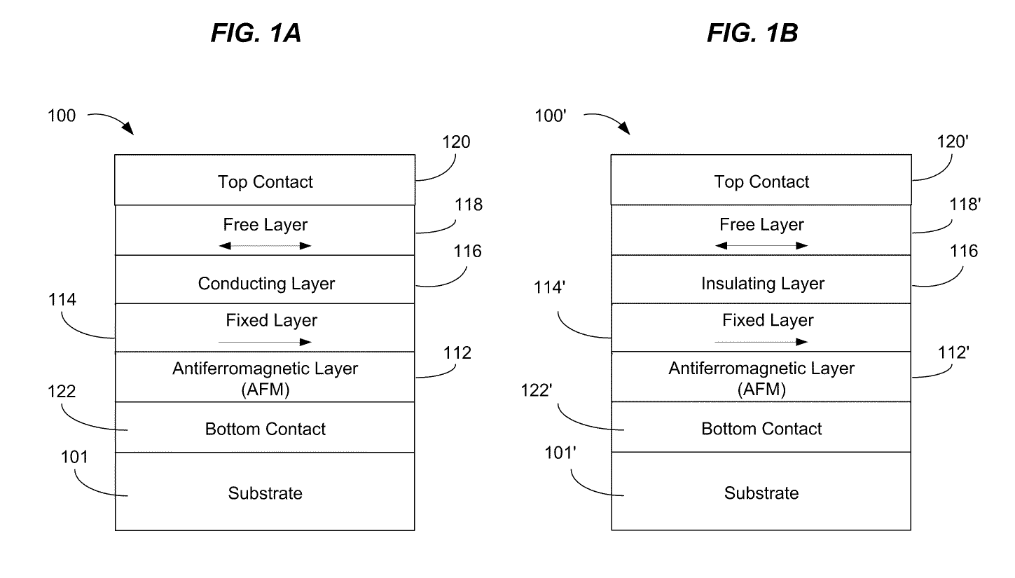

FIGS. 1A and 1B depict magnetic element layers of two exemplary multilayer magnetic elements 100 and 100′. A non-magnetic spacer layer is provided between the fixed layer and the free layer to provide magnetic coupling between the free layer and the fixed layer. Such devices can be structured for switching a free layer by applying an external magnetic field or by applying an electric current. Such elements are formed in arrays for digital memory devices and applications.

In FIG. 1A, the magnetic element 100 is a spin valve on a substrate 101 and includes an optional antiferromagnetic (AFM) layer 112, a fixed layer 114, a conductive spacer layer 116 and a free layer 118. The fixed layer 114 and the free layer 118 are ferromagnetic. The free layer 118 is depicted as having a changeable magnetization with two possible directions as indicated by two arrows. The magnetization of the free layer 118 is free to rotate in response to an applied control magnetic field in a field switching design or an applied control electric current based on the spin torque transfer. The conductive spacer layer 116 is nonmagnetic. The optional AFM layer 112 is used to pin the magnetization of the fixed layer 114 in a particular direction. In absence of an AFM, the fixed layer direction can be provided by shape anisotropy or crystalline anisotropy. After post-deposition annealing, the ferromagnetic layer 114 is pinned with a fixed magnetization as indicated by the arrow. Two electrical contacts, the top contact 120 and the bottom contact 122, can be provided as electrical contacts of the magnetic element 100 and, in a design that switches based on the spin torque transfer, can be used to drive the current through the magnetic element 100. Other layers, such as seed layers formed between the substrate and a stack of layers for the magnetic element and capping layers formed on top of the stack of the layers, may also be formed in FIG. 1A and FIG. 1B below.

The magnetic element 100′ depicted in FIG. 1B is a magnetic tunneling junction (MTJ). Portions of the magnetic tunneling junction 100′ are analogous to the spin valve 100. Thus, the magnetic element 100′ includes an optional AFM layer 112′, a fixed layer 114′ having a fixed layer magnetization, a insulating barrier layer 116′, a free layer 118′ having a changeable magnetization. The barrier layer 116′ is sufficiently thin for electrons to tunnel through in the magnetic tunneling junction 100′.

The relationship between the resistance to the current flowing across the MTJ or SV and the relative magnetic direction between the two ferromagnetic layers in the TMR or MR effect can be used for nonvolatile magnetic memory devices to store information in the magnetic state of the magnetic element. Magnetic random access memory (MRAM) devices based on the TMR or MR effect, for example, can be an alternative of and compete with electronic RAM devices. In such devices, one ferromagnetic layer is configured to have a fixed magnetic direction and the other ferromagnetic layer is a “free” layer whose magnetic direction can be changed to be either parallel or opposite to the fixed direction and thus operate as a recording layer. Information is stored based on the relative magnetic direction of the two ferromagnetic layers on two sides of the barrier of the MTJ or SV. For example, binary bits “1” and “0” can be recorded as the parallel and anti-parallel orientations of the two ferromagnetic layers in the MTJ or SV. Recording or writing a bit in the MTJ or SV can be achieved by switching the magnetization direction of the free layer, e.g., by a writing magnetic field generated by supplying currents to write lines disposed in a cross stripe shape, by a current flowing across the MTJ or SV based on the spin transfer effect, or by other means.

Magnetic random access memory devices utilizing a spin transfer effect in switching be operated under a low switching current density, J_{c}, below 10⁷ A/cm² (e.g., around or below 10⁶ A/cm²) for practical device applications. This low switching current density advantageously allows for formation of arrays of densely packed memory cells (e.g., sub-micron lateral dimensions) with a high bias current. The reduction of the spin-transfer switching current density J, can be critical for making MRAM devices featured by a fast operation speed, low power consumption, and a high spatial density of memory cells. With decreased technology node of memory devices, however, thermal stability increasingly affects the performance of these devices. During periods of latency when an MTJ preserves a stored datum, the magnetization in the free layer is not entirely static and may change due to thermal fluctuations that allow the magnetic moments within the free layer to oscillate or precess. The random nature of these fluctuations allows the occurrence of rare, unusually large fluctuations that may result in the reversal of the free-layer magnetization.

In devices with arrayed magnetic elements, neighboring magnetic cells are major contributors to the net external field that acts on a given free layer moment, giving rise to cross-talk that can limit the lifetime of stored information and lead to loss of stored data bits. The stability of data stored in an array of identical MTJ cells depends strongly, therefore, on the magnitude and configuration of the magnetic field produced by each cell in the space around it.

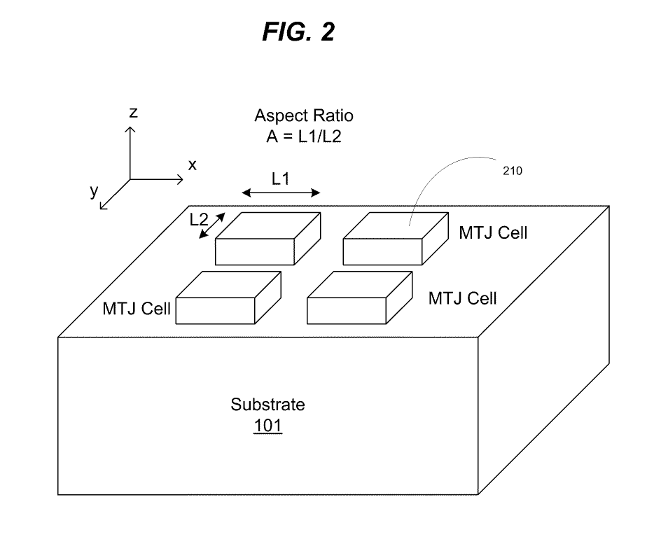

FIG. 2 shows an example of a magnetic memory chip device where a two-dimensional array of magnetic cells based on the cell design in FIG. 1A, FIG. 1B or other designs monolithically formed on the substrate 101. A Cartesian coordinate (x, y, z) is used to illustrate different dimensions of the chip. Rectangular blocks in FIG. 2 are used to represent relative positions of MTJ cells and dimensions of each MTJ cell of the memory chip. In an actual device, each cell may be elliptically shaped and elongated along the x direction. Each MTJ cell can be fabricated on a metal via plug on the substrate. Each MTJ cell is illustrated to have a length L1 along the x direction and a length L2 along the y direction, wherein both x and y directions are parallel to the plane of the substrate. The aspect ratio of each MTJ cell in the x and y directions is A=L1/L2. In order to increase the storage areal density of the memory chip, both L1 and L2 are reduced to increase the number of MTJ cells in a given area in a memory device.

One known technique to increase the thermal stability of the MTJ cells uses the shape anisotropy of the magnetic recording layer of the magnetic cell to spatially favor a particular magnetization direction. In some cases, large shape anisotropy may be used to compensate for the insufficient amount of intrinsic crystalline anisotropy. Assuming Ll is the length along the direction along which the shape anisotropy is desired, the aspect ratio A=L1/L2 should be large in order to maintain a sufficiently large shape anisotropy. However, the scaling of the magnetic cell embedded into CMOS manufacturing process may impose limitations to the size, geometry and aspect ratio (A) of the cell. For example, the 130-nm-node CMOS technology can limit the upper limit of the aspect ratio A of the MTJ cells to about 1.77 if the overlap rule is ignored and to around 1 if the overlap rule is taken into account for designing a via size of 0.23 μm with an overlap of 0.055 μm per side. When the more advanced technology node of 90 nm is used, the aspect ratio A of the MTJ cells is actually reduced to 1 from 1.67 for a via size of 0.15 μm with an overlap of 0.03 μm per side. Therefore, due to the CMOS fabrication limitations to the aspect ratio A of each cell, it may be difficult to achieve both a large aspect ratio A and a high cell density at the same time.

Spin-transfer-torque (STT) random access memory (RAM) bits can be patterned using a single lithography step followed by an etch step to pattern the MTJ film. In advanced process nodes, the smallest feature is much smaller than the wavelength of the light and thus it can be difficult to provide good shape control using such processes. For a STT-RAM element or bit with in-plane magnetization, the design that has a narrow width and a high aspect ratio provides high shape anisotropy and thus high thermal stability for a given device area. Thus there is a strong preference to reduce the bit width, so that the minimum dimension of the bit is smaller than the process node for the underlying transistors. The present fabrication techniques can be implemented by using an atomically precise deposition technique to determine at least one of the dimensions, which enables smaller feature sizes with better uniformity than those resolvable using various photolithography techniques. The present process can be used to form a high aspect ratio mask for the patterning process that also serves as an electrical contact, increasing the process margin for a subsequent planarization step, increasing manufacturability. A highly permeable spacer layer can be formed between neighboring rows of bits to increase the bit stability and reduce the bit to bit interactions, enabling dense STT-RAM arrays. The techniques described here are also applicable to MTJs with perpendicular magnetization.

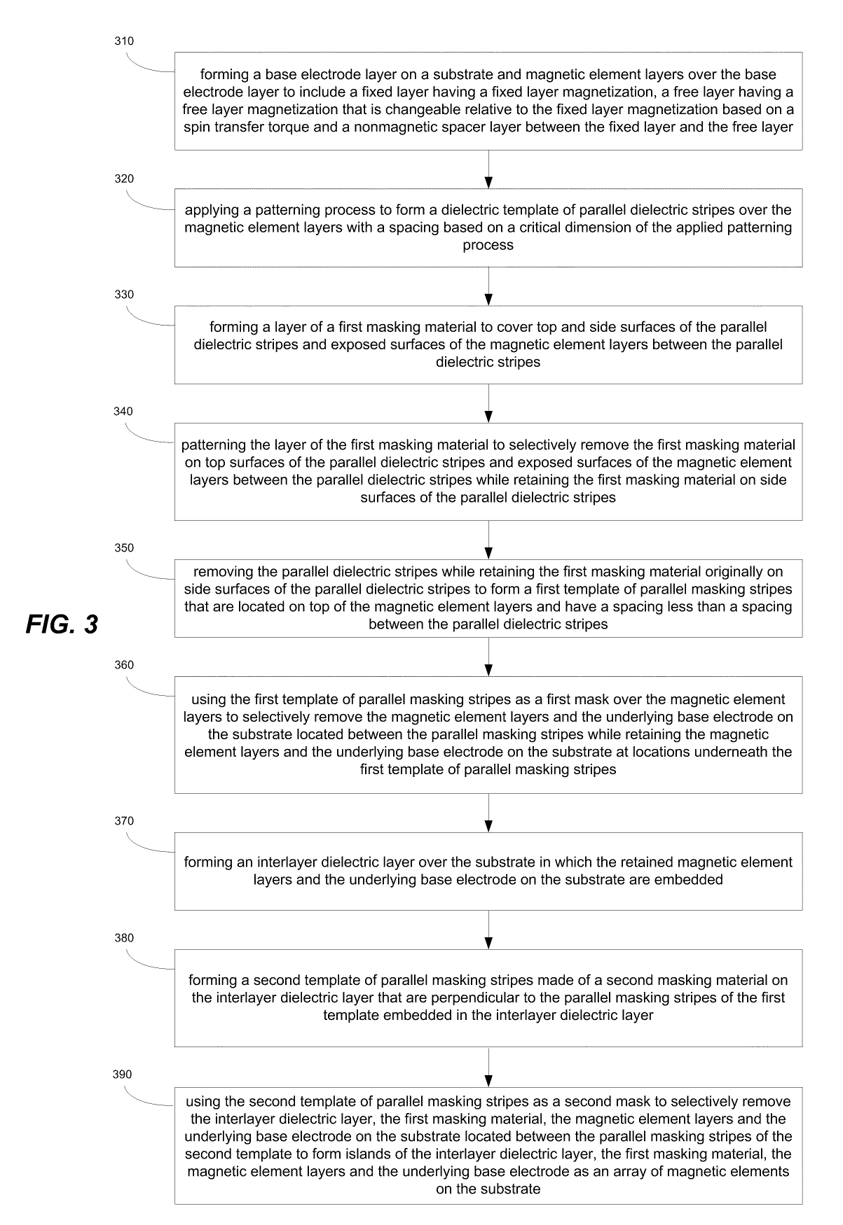

FIG. 3 shows an example of a fabrication process for forming an array of magnetic elements on a substrate where each magnetic element has one dimension less than the critical dimension of a patterning process used in the fabrication. In this example, a base electrode (BE) layer is first formed on a substrate. Suitable magnetic element layers, e.g., MTJ layers in FIG. 1A or SV layers in FIG. 1B, are then formed over the base electrode layer to include, e.g., a fixed layer having a fixed layer magnetization, a free layer having a free layer magnetization that is changeable relative to the fixed layer magnetization based on a spin transfer torque and a nonmagnetic spacer layer between the fixed layer and the free layer. This completes the initial fabrication step (310). The magnetic element layers of the magnetic elements are structured to exhibit a magnetization that either is substantially perpendicular to the substrate or substantially lies within a plane of the substrate.

Next, a template is formed. A patterning process is applied to form a removable template of parallel stripes over the magnetic element layers with a spacing (320). This spacing can be based on a critical dimension of the applied patterning process and may be close to the critical dimension. This patterning process can be a photolithography patterning process in some implementations and, in other implementations, can include a photolithography patterning process coupled with a subsequent etching step. The material for the template can be selectively removed while leaving the sidewall material in place. One exemplary class of materials for the template is dielectric materials. The following examples use a dielectric material to form the removable template. A layer of a first masking material is formed to cover top and side surfaces of the parallel dielectric stripes and exposed surfaces of the magnetic element layers between the parallel dielectric stripes (330). The first masking material is an electrically conductive material such as a metal and a portion of the first masking material will constitute part of the top of an MTJ element through which an electrical current for operating the MTJ via the spin transfer torque. The layer of the first masking material is patterned to selectively remove the first masking material on top surfaces of the parallel dielectric stripes and exposed surfaces of the magnetic element layers between the parallel dielectric stripes while retaining the first masking material on side surfaces of the parallel dielectric stripes (340). The parallel dielectric stripes are subsequently removed while retaining the first masking material originally on side surfaces of the parallel dielectric stripes to form a first template of parallel masking stripes that are located on top of the magnetic element layers and have a spacing less than a spacing between the parallel dielectric stripes (350). This completes the formation of the first template.

The above first template of parallel masking stripes is used as a first mask over the magnetic element layers to selectively remove the magnetic element layers and the underlying base electrode on the substrate located between the parallel masking stripes while retaining the magnetic element layers and the underlying base electrode on the substrate at locations underneath the first template of parallel masking stripes (360). An interlayer dielectric layer is formed over the substrate in which the retained magnetic element layers and the underlying base electrode on the substrate are embedded (370). A second template of parallel masking stripes made of a second masking material is further formed on the interlayer dielectric layer (380). The stripes of this second template are perpendicular to the parallel masking stripes of the first template embedded in the interlayer dielectric layer. Next, the second template of parallel masking stripes is used as a second mask to selectively remove the interlayer dielectric layer, the first masking material, the magnetic element layers and the underlying base electrode on the substrate located between the parallel masking stripes of the second template to form islands of the interlayer dielectric layer, the first masking material, the magnetic element layers and the underlying base electrode as an array of magnetic elements on the substrate (390).

The above fabrication process is a double patterning process that utilizes two sets of templates of parallel lines. The parallel lines of the templates tend to be easy to image and control using advanced lithography techniques such as phase shifting masks and off-axis illumination), where the first diffraction order is available for imaging at sizes much smaller than the wavelength. The above described first template provides a self-aligned sidewall spacer process to define a metallic etch mask that also serves as device top contact. This double patterning process can be used to decrease the minimum feature size and improve shape control and the bit stability.

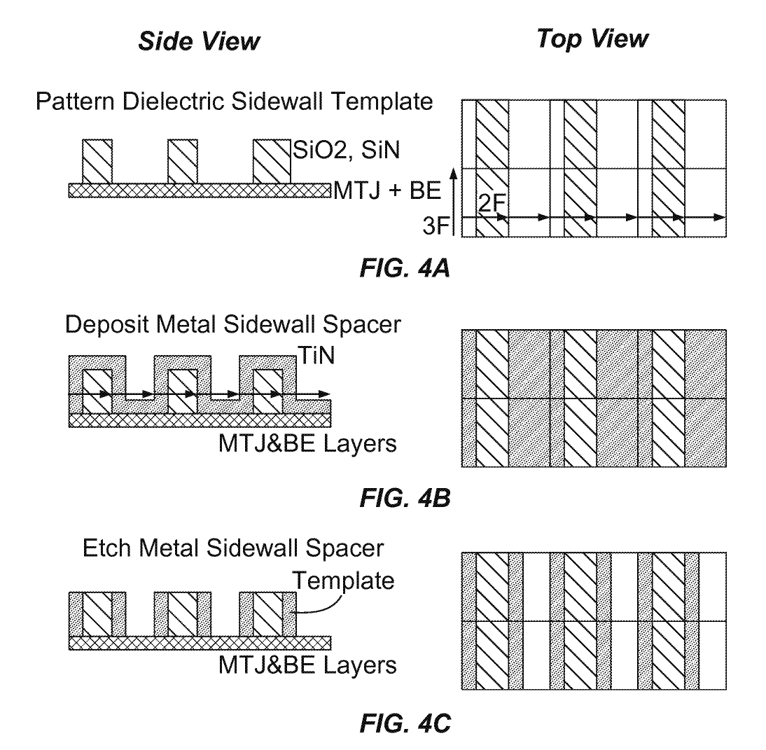

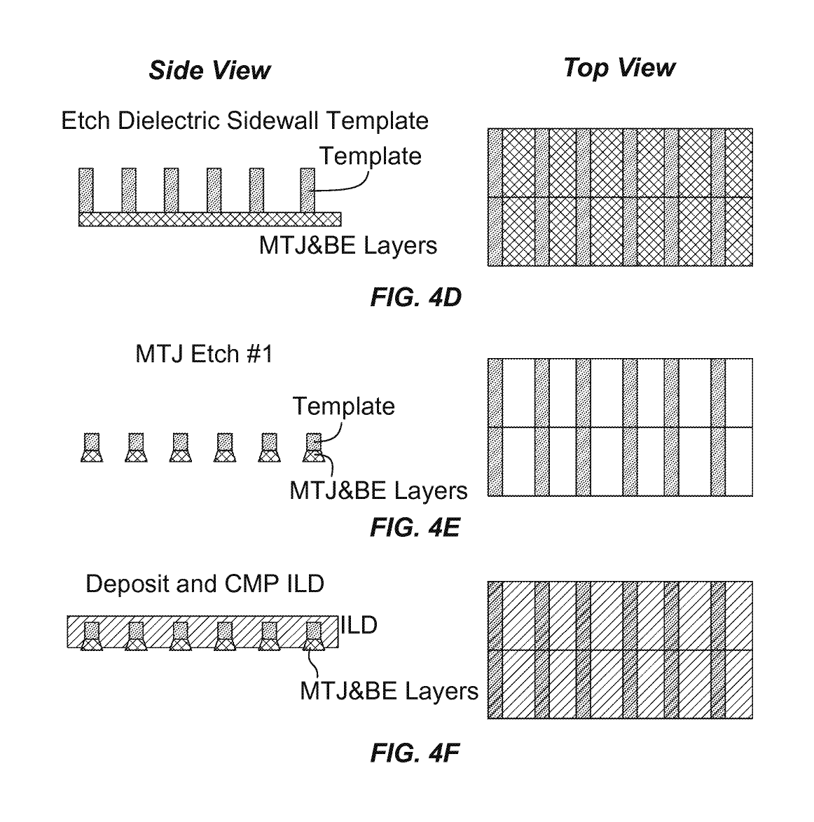

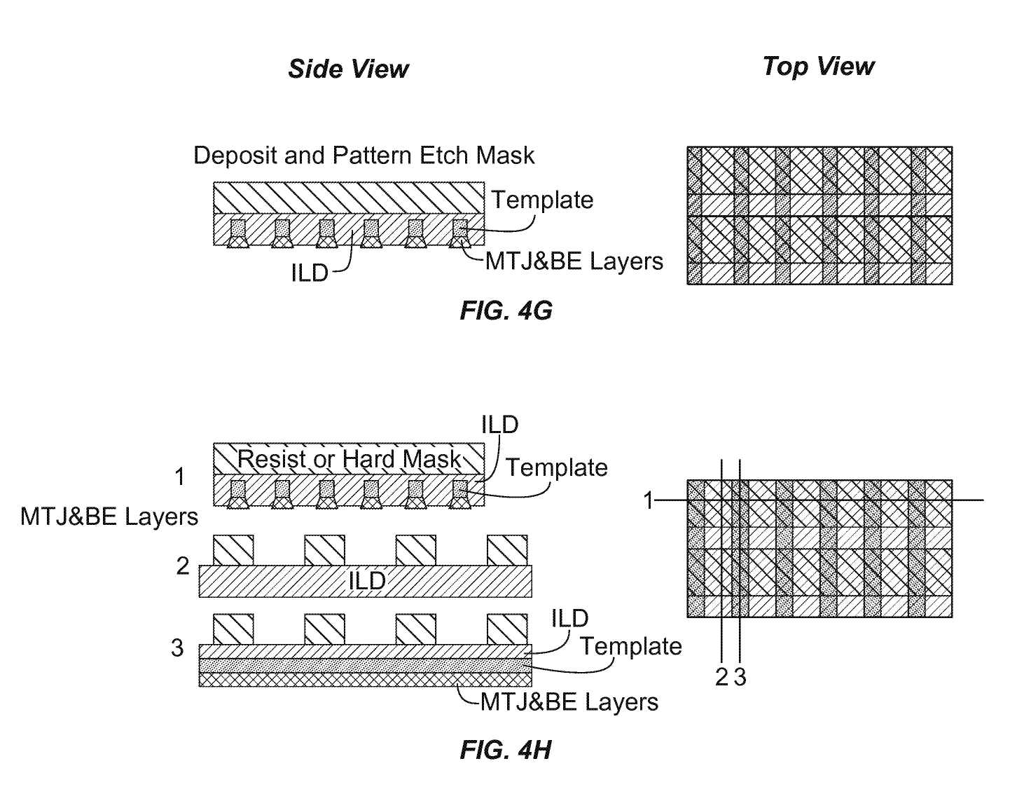

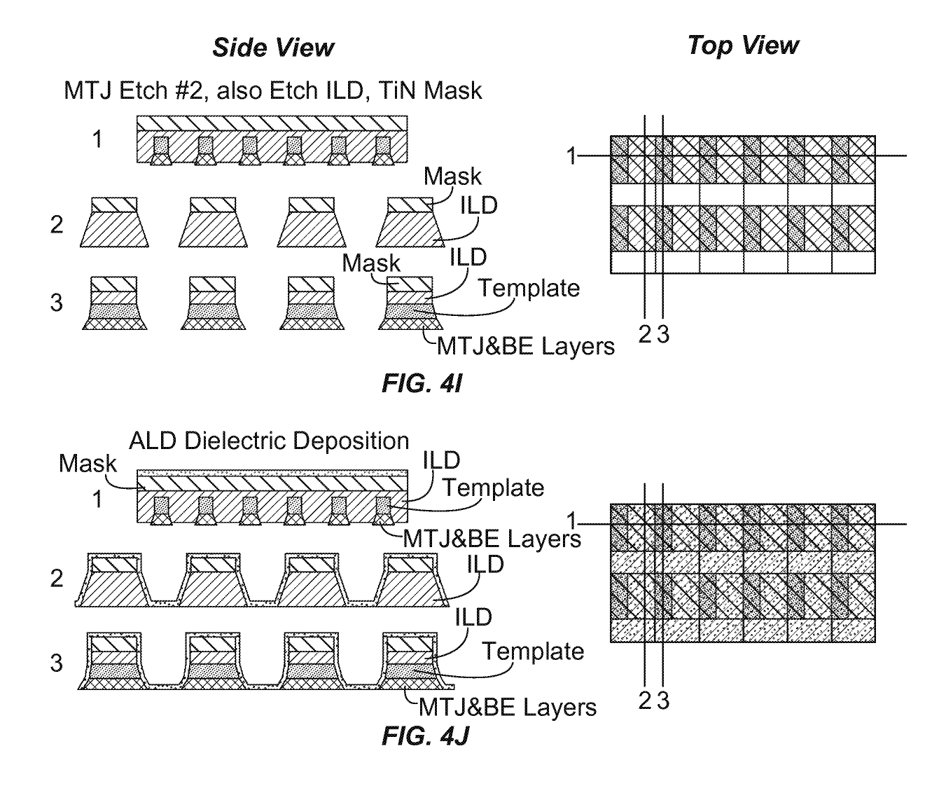

FIGS. 4A through 4J shows an exemplary implementation of the fabrication process in FIG. 3. Each figure shows a top view of the structure and one or more side views of the structure. First a dielectric layer such as SiO₂ or SiN is patterned into lines using lithography and etching (FIG. 4A). Then TiN, WN, or a RIE-patternable metallic layer is deposited using an isotropic deposition method, such as Atomic Layer Deposition (ALD) or Plasma Enhanced Chemical Vapor Deposition (PECVD) as shown in FIG. 4B. After the metal is deposited, an anisotropic reactive-ion-etch (RIE) step is used to remove the metal from surfaces parallel to the wafer surface, while leaving the metal on the sidewall of the dielectric layer (FIG. 4C). Next, the dielectric SiN or SiO₂ is removed using a second RIE step (or wet chemical etch) that has good selectivity between the dielectric and metal (FIG. 4D). Since each resist feature has two sidewalls, the minimum pitch of the resulting metal etch mask is the pitch of the lithographically defined features. The use of an atomically precise deposition technique to define the device enables its width to be smaller than the minimum feature size for the rest of the STT-RAM cell. In addition, the patterns can have a high aspect ratio, making the subsequent planarization and top contact steps easier to control in manufacturing.

After the metal etch mask is formed, the MTJ film and bottom electrode are patterned using RIE (FIG. 4E). If needed, a thin protective dielectric can be deposited after etching through either the free layer, or full MTJ stack, to protect the MTJ free layer and sidewall at the tunnel barrier from RIE damage while patterning the pinning AFM and/or bottom electrode metals. If this protective dielectric is deposited, the anisotropic nature of the etch through bottom AFM and/or bottom electrode will leave device protected on the device sidewall at the free layer and tunnel barrier. After etching through the MTJ and bottom electrode, the wafer is then covered with a dielectric, and planarized using chemical-mechanical polishing (CMP), finishing the patterning of the short dimension of the STT-RAM bit (FIG. 4F).

After the CMP step, the second, longer dimension of the STT-RAM bit is patterned. This longer dimension may be two or more times longer than the first dimension in some devices and, as such, a lithography-etch scheme can be used, where the photoresist is used as a mask to pattern either the full set of layers (now including the MTJ, bottom electrode, and the first dielectric refill), or more likely, the photoresist is used to pattern a hard mask material, that then is used to mask the subsequent etching through the underlying materials (FIG. 4G). This patterning step now needs to etch through the MTJ film or the first dielectric refill (depending on the location), as well as the first metal hard mask (TiN or WN) and bottom electrode materials. After etching through the free layer, tunnel barrier, and pinned layers, a dielectric spacer can be deposited with an isotropic deposition technique can be used to protect the device sidewall from subsequent etching through the bottom AFM and bottom electrode layers, as described above for the first MTJ/bottom electrode etch step (FIGS. 4H and 4I). After all etching is complete, a thin dielectric layer is deposited using an isotropic deposition technique (ALD, CVD) to insulate the bits from one another (FIG. 4J). In each of FIGS. 4H, 4I and 4J, three side views of the structure are provided where each side view is labeled by a numeral “1,” “2” or “3” and corresponds to a cross section view produced along a line that is shown in the top-view figure on the right hand side and is labeled by the same numeral.

In the process in FIG. 3, the sidewall process can also be used for the second dimension patterning of the second template. This process of using the sidewall process for the second dimension patterning enables better control of the second dimension at smaller sizes and enable the use of less expensive photolithography tools with a lower resolution. A method for fabricating a magnetic element array on a substrate based on applying the sidewall process to pattern both templates can include forming a base electrode layer on a substrate and magnetic element layers over the base electrode layer to include a fixed layer having a fixed layer magnetization, a free layer having a free layer magnetization that is changeable relative to the fixed layer magnetization based on a spin transfer torque, and a nonmagnetic spacer layer between the fixed layer and the free layer; applying a patterning process to form a template of parallel template stripes over the magnetic element layers with a spacing; forming a layer of a first masking material, that is electrically conductive, to cover top and side surfaces of the parallel template stripes and exposed surfaces of the magnetic element layers between the parallel template stripes; patterning the layer of the first masking material to selectively remove the first masking material on top surfaces of the parallel template stripes and exposed surfaces of the magnetic element layers between the parallel template stripes while retaining the first masking material on side surfaces of the parallel template stripes; and removing the parallel template stripes while retaining the first masking material originally on side surfaces of the parallel template stripes to form a first template of parallel masking stripes that are located on top of the magnetic element layers and have a spacing less than a spacing between the parallel template stripes. Next in this method, the first template of parallel masking stripes is used as a first mask over the magnetic element layers to selectively remove the magnetic element layers and the underlying base electrode on the substrate located between the parallel masking stripes while retaining the magnetic element layers and the underlying base electrode on the substrate at locations underneath the first template of parallel masking stripes. An interlayer dielectric layer is formed over the substrate in which the retained magnetic element layers and the underlying base electrode on the substrate are embedded. The second template of parallel masking stripes, which is made of a second masking material, is formed on the interlayer dielectric layer that are perpendicular to the parallel masking stripes of the first template embedded in the interlayer dielectric layer.

In forming of the second template of parallel masking stripes, the sidewall process is used for the second time and includes forming an additional template of parallel template stripes over the interlayer dielectric layer; forming a layer of a third masking material to cover top and side surfaces of the parallel template stripes of the additional template and exposed surfaces of the underlying interlayer dielectric layer between the parallel template stripes of the additional template, and patterning the layer of the third masking material to selectively remove the third masking material on top surfaces of the parallel template stripes of the additional template and exposed surfaces of the underlying interlayer dielectric layer between the parallel template stripes of the additional template while retaining the third masking material on side surfaces of the parallel template stripes of the additional template. The parallel template stripes of the additional template are then removed while retaining the third masking material originally on side surfaces of the parallel template stripes of the additional template to form the second template of parallel masking stripes made of the second masking material.

Next, the second template of parallel masking stripes is used as a second mask to selectively remove the interlayer dielectric layer, the first masking material, the magnetic element layers and the underlying base electrode on the substrate located between the parallel masking stripes of the second template to form islands of the interlayer dielectric layer, the first masking material, the magnetic element layers and the underlying base electrode as an array of magnetic elements on the substrate.

The above process of using the sidewall process for the second dimension patterning can be useful in patterning MTJs with perpendicular magnetizations, whose stability is not determined by the shape and can be patterned into small circles or squares to reduce the area of each MTJ element and thus the overall area occupied by the MTJ array.

The above fabrication process can also include steps that provide magnetic permeable features to stabilize the bits. Magnetic elements are often subject to external disturbance to each free layer. Such external disturbance can cause unintended, incidental switching of the magnetization of the magnetic element that is not caused by the control magnetic field or current. This unintended switching of a free layer destroys the data bit stored in the free layer and thus is undesirable. The external disturbance that leads to the unintended switching can come from one or more sources. For example, a stray magnetic field that is generated by a source outside a magnetic element or the device can cause the unintended switching. Thermal fluctuations in the device can also cause the unintended switching. For yet another example, in an array of magnetic elements, the magnetic field or flux of one magnetic element can be present at a neighboring magnetic element in the array and thus may cause unintended switching of that neighboring magnetic element. The unintended switching of a free layer in a magnetic element can occur in magnetic elements that are designed to exhibit an in-plane magnetic anisotropy where the magnetic moments of the free layer and the fixed layer are substantially in the plane of the substrate and magnetic elements that are designed to exhibit a perpendicular magnetic anisotropy where the magnetic moments of the free layer and the fixed layer are substantially perpendicular to the plane of the substrate. As the size of a MTJ cell reduces, the magnetization direction of the free layer in each cell can become increasingly sensitive to various factors such as thermal fluctuations, external field disturbances or superparamagnetism. This is in part because the magnetic energy due to the magnetic volume of the MTJ or SV for storing and maintaining a digital bit reduces with the size of the cell. When the magnetic energy for storing and maintaining the digital bit is reduced with the cell size below a critical level, the energy of the disturbance may be sufficient to alter the magnetic state of the cell and thus change the stored bit. Therefore, the magnetization direction of the free layer in a sufficiently small cell may unexpectedly change because of any one or a combination of these and other factors and thus alter or erase the stored information. In some devices, a magnetically permeable material structure can be formed on the substrate to locally confine a magnetic flux of each of the magnetic elements from reaching an adjacent magnetic element. This structure stabilizes arrayed magnetic elements against inter-element interference and other disturbances and improves the performance of magnetic memory devices based on such arrayed magnetic elements, especially arrays with small element pitches and high areal density arrays. Some examples of using a magnetically permeable material structure in magnetic devices are provided in U.S. patent application Ser. No. 12/539,544 entitled “Magnetic Element Arrays Having Magnetic Flux Guides” and filed on Aug. 11, 2009, which is incorporated by reference as part of the disclosure of this document.

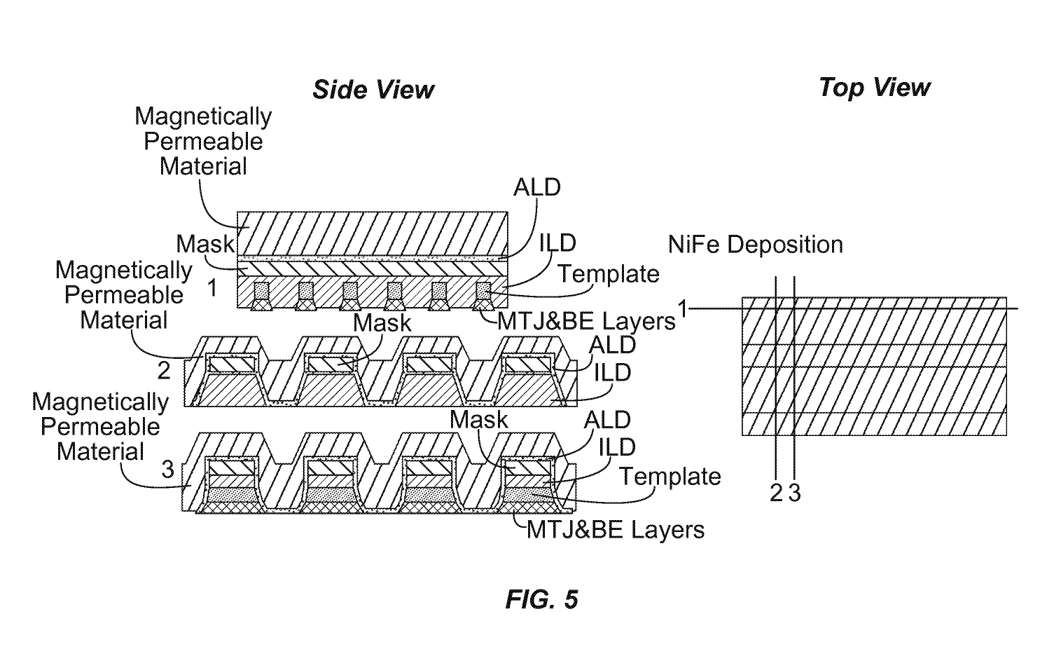

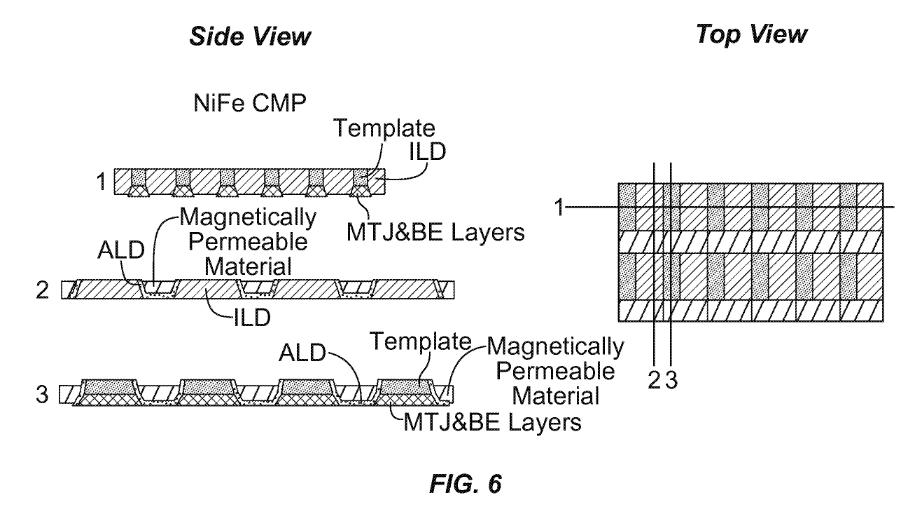

FIGS. 5 and 6 show two examples for fabricating magnetically permeable structures on an array of magnetic elements to enhance the magnetic stability of the magnetic elements. In each of FIGS. 5 and 6, three side views of the structure are provided where each side view is labeled by a numeral “1,” “2” or “3” and corresponds to a cross section view produced along a line that is shown in the top-view figure on the right hand side and is labeled by the same numeral.

In FIG. 5, a layer of a soft permeable material is deposited after the process in FIG. 4J. This soft permeable material can be a metal layer, such as permalloy (NiFe), in some applications, and can be an insulating layer in other applications. This soft magnetic material is used to enhance the bit stability, and reduce the bit to bit interaction. The shape anisotropy of the bit is equivalent to placing magnetic charges at the ends of the device in the long direction, and image charges are induced in a nearby soft magnetic material, increasing the bit stability.

In FIG. 6, a highly permeable layer can be introduced in the MTJ stack above or below the normal MTJ, or in the bottom electrode, to increase the bit stability. This structure introduces a low permeability path between the two ends of the device along the long axis, reducing the de-magnetizing field and increasing the bit stability.

After the deposition of the high permeability material, CMP is used to planarize the wafer and expose the initial metal etch mask/contact (TiN/WN). An additional interlayer dielectric layer can be deposited contact vias can be etched in the additional interlayer dielectric layer. This dielectric layer should be chosen such that it can be etched preferentially to the dielectric layers deposited on the MTJ sidewalls during the second patterning sequence and between the bits in the first patterning sequence.

In fabrication of some devices, a permeable magnetic material can be used to refill in both directions after the MTJ etch steps. In one implementation, two materials are deposited at the refill step after patterning the short dimension; a dielectric layer followed by a permeable material (e.g., a conducting ferromagnetic metal like permalloy). The thickness of the dielectric layer is large enough to enable a top contact to be brought down to the device top without contacting the conducting permeable material. Contacting the conducting permeable material would undesirably cause shorting of different bit lines together. In the case of MTJs with in-plane magnetization, using a thicker dielectric spacer in the short dimension of the bit enables image charges closer to the bit, reinforcing the shape anisotropy. If a highly permeable layer is included in the MTJ stack or bottom electrode, a low reluctance path is formed which helps to guide the flux return path along the long axis of the bit, increasing the uniaxial anisotropy and hence the bit stability. In the case of MTJ's with perpendicular magnetization, the bits can be any shape, and the smallest bit size would be achievable using the self-aligned sidewall process for both directions. For the case of perpendicular magnetization, using a combination dielectric/soft permeable material hybrid refill provides a low reluctance path for the flux from the MTJ to return without reducing bit to bit interactions and enabling high density STT-RAM arrays.

The present fabrication processes enable STT-RAM arrays to be extended to smaller bit sizes by using deposition and etching to define the minimum dimension, rather than lithography. This is advantageous for in-plane MTJs, as smaller, higher aspect ratio bits have the best stability for a given device area. The use of a soft permeable material to separate lines of bits will reinforce the shape anisotropy, and minimize bit to bit interactions for dense memory arrays. For MTJs with perpendicular magnetizations, a 2-step self aligned sidewall process enables bit patterning at much smaller dimensions, and can be implemented with less expensive lithography tools, as the size is determined by deposition and etching steps, with only the bit spacing defined by the lithography tool. In the case of an MTJ with perpendicular anisotropy, the use of permeable material in the refill step after MTJ/bottom electrode etching isolates neighboring bits from the return flux, reducing/eliminating bit to bit interactions. In order for the permeable material to be effective in guiding the return flux from the free layer, the permeable material can be selected to have a short exchange length or be composed of a granular material.

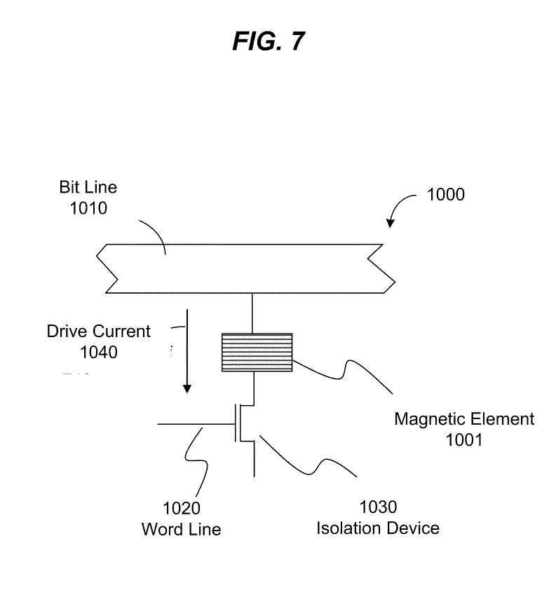

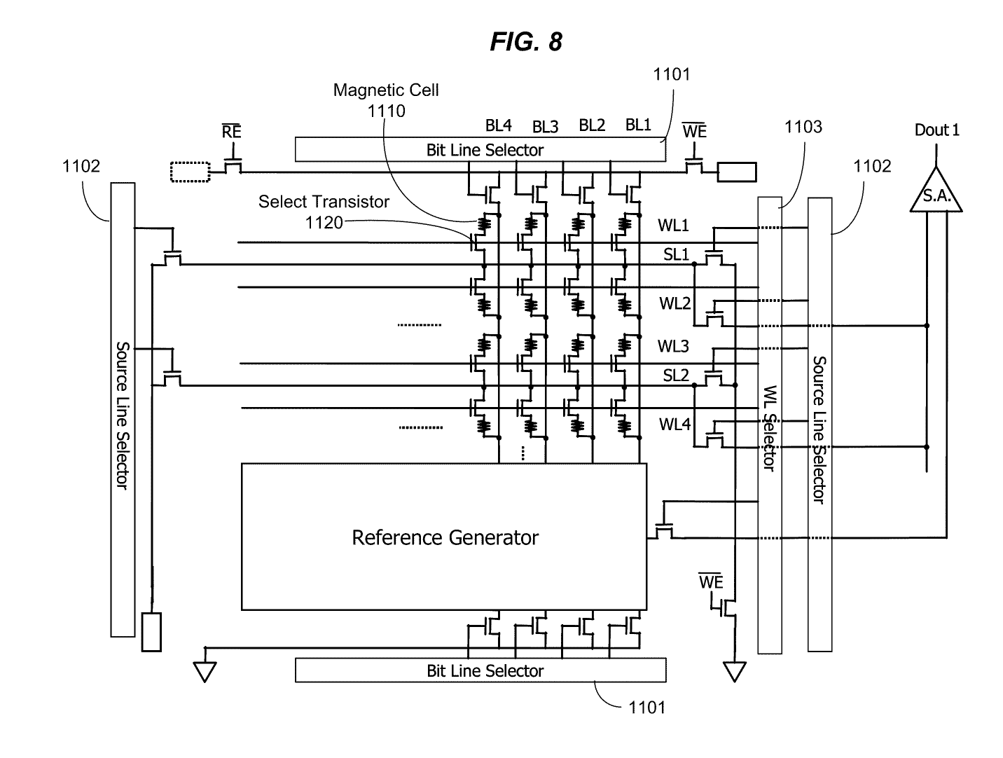

The above magnetic element array designs can be implemented for both field switching of the free layer (if the permeable inter-element features are not included) and switching based on the spin torque transfer. FIGS. 7 and 8 described circuitry for switching based on the spin torque transfer in arrayed magnetic memory devices.

FIG. 7 illustrates a part of an exemplary magnetic device 1000 that includes an array of unit cells. Each unit cell includes a magnetic element 1001 based on the spin-transfer torque effect. A conductor line 1010 labeled as “bit line” is electrically coupled to the magnetic element 1001 by connecting to one end of the magnetic element 10 to supply an electrical drive current 1040 through the layers of the magnetic element 801 to effectuate the spin-transfer torque effect in the magnetic element 1001. An electronic isolation device 1030, such as an isolation transistor, is connected to one side of the magnetic element 1001 to control the current 1040 in response to a control signal applied to the gate of the transistor 1030. A second conductor line 1020 labeled as “word line” is electrically connected to the gate of the transistor 1030 to supply that control signal. In operation, the drive current 1040 flows across the layers in the magnetic element 1001 to change magnetization direction of the free layer when the current 1040 is greater than a switching threshold which is determined by materials and layer structures of the magnetic element 1001. The switching of the free layer in the magnetic element 1001 is based on the spin-transfer torque caused by the drive current 1040 alone without relying on a magnetic field produced by the lines 1010 and 1020 or other sources.

The magnetic element 1001 based on the spin-transfer torque effect can be implemented in various configurations, such as an MTJ, a spin valve, a combination of an MTJ and a spin valve, a combination of two MTJs and other configurations. Each of the free and pinned layers can be a single magnetic layer or a composite structure of multiple layers magnetically coupled together.

FIG. 8 shows an exemplary circuit that operates an arrayed magnetic memory device based on spin-transfer torque switching. Each cell 1110 is connected in series to a select transistor 1120 which corresponds to the isolation device 1030 in FIG. 7. As illustrated, a bit line selector 1101, a source line selector 1102 and a word line selector 1103 are coupled to the cell array to control the operations of each cell.

While this document contains many specifics, these should not be construed as limitations on the scope of an invention or of what may be claimed, but rather as descriptions of features specific to particular embodiments of the invention. Certain features that are described in this document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or a variation of a subcombination.

Only a few implementations are disclosed. However, variations and enhancements of the described implementations and other implementations can be made based on what is described and illustrated in this document.

1. A method for fabricating a magnetic element array on a substrate, comprising:
forming a base electrode layer on a substrate and magnetic element layers over the base electrode layer to include a fixed layer having a fixed layer magnetization that is parallel to the substrate, a free layer having a free layer magnetization that is parallel to the substrate and is changeable relative to the fixed layer magnetization based on a spin transfer torque, and a nonmagnetic spacer layer between the fixed layer and the free layer;
applying a patterning process to form a template of parallel template stripes over the magnetic element layers with a spacing;
forming a layer of a first masking material, that is electrically conductive, to cover top and side surfaces of the parallel template stripes and exposed surfaces of the magnetic element layers between the parallel template stripes;
patterning the layer of the first masking material to selectively remove the first masking material on top surfaces of the parallel template stripes and exposed surfaces of the magnetic element layers between the parallel template stripes while retaining the first masking material on side surfaces of the parallel template stripes;
removing the parallel template stripes while retaining the first masking material originally on side surfaces of the parallel template stripes to form a first template of parallel masking stripes that are located on top of the magnetic element layers and have a spacing less than a spacing between the parallel template stripes;
using the first template of parallel masking stripes as a first mask over the magnetic element layers to selectively remove the magnetic element layers and the base electrode on the substrate located between the parallel masking stripes while retaining the magnetic element layers and the base electrode on the substrate at locations underneath the first template of parallel masking stripes;
forming an interlayer dielectric layer over the substrate in which the retained magnetic element layers and the base electrode on the substrate are embedded;
forming a second template of parallel masking stripes made of a second masking material on the interlayer dielectric layer that are perpendicular to the parallel masking stripes of the first template embedded in the interlayer dielectric layer;
using the second template of parallel masking stripes as a second mask to selectively remove the interlayer dielectric layer, the first masking material, the magnetic element layers and the base electrode on the substrate located between the parallel masking stripes of the second template so as to expose the substrate along surface stripes having a width equal to the spacing between the parallel masking stripes of the second template and form islands of the interlayer dielectric layer, the first masking material, the magnetic element layers and the base electrode corresponding to the magnetic element array on the substrate, such that each of the magnetic elements has a short dimension that is equal to the width of the first template's parallel masking stripes, and a long dimension that is equal to the width of the second template's masking stripes, and such that opposite side surfaces of a magnetic element that correspond to the short dimension are exposed to the substrate along respective surface stripes adjacent to the magnetic element, and other opposite side surfaces of the magnetic element that correspond to the long dimension are in contact with the interlayer dielectric layer which fills the space between side surfaces of adjacent magnetic elements corresponding to the long dimension to provide electrical insulation between adjacent magnetic elements;
depositing a top dielectric layer over the array of magnetic elements to cover the exposed side surfaces of each magnetic element that correspond to the short dimension and to further cover the exposed substrate over the surface stripes to provide electrical insulation between adjacent magnetic elements; and
forming a planar layer of a soft magnetically permeable material over the surface stripes of the substrate that are covered by the top dielectric layer, the formed planar layer filling the space between side surfaces of adjacent magnetic elements that correspond to the short dimension and that are covered by the top dielectric layer, such that effective magnetic charges created at ends of each magnetic element in the long dimension induce image magnetic charges in the planar layer of the soft magnetically permeable material to increase stability of each magnetic element and to reduce interaction between adjacent magnetic elements.

2. The method as in claim 1, wherein the interlayer dielectric layer is formed by:
depositing an interlayer dielectric material to cover the retained magnetic element layers and the base electrode on the substrate; and
applying a chemical mechanical polishing process to the deposited interlayer dielectric material to form the interlayer dielectric layer with a flat top surface on which the second template of parallel masking stripes is subsequently formed.

3. (canceled)

4. The method as in claim 1, wherein the first masking material is a nitride.

5. The method as in claim 4, wherein the first masking material is TiN or WN.

6. The method as in claim 1, wherein the first masking material is a metal layer.

7. The method as in claim 6, wherein:
the first masking material is a metal layer that can be patterned by a reactive ion etching process; and
an anisotropic reactive ion etching process is used to pattern the metal layer to form the first template of parallel masking stripes on top of the magnetic element layers.

8. The method as in claim 1, wherein the template of parallel template stripes formed over the magnetic element layers is formed of an oxide or nitride.

9. The method as in claim 1, wherein the template of parallel template stripes is formed by:
depositing a dielectric material on top of the magnetic element layers; and
applying the patterning process to selectively remove the dielectric material to form the template of parallel template stripes.

10. The method as in claim 1, wherein the patterning process for forming the parallel template stripes includes a photolithographic process and the first template of parallel masking stripes has a feature dimension less than a critical dimension of the photolithographic process.

11. The method as in claim 1, wherein the patterning process for forming the parallel template stripes includes a photolithographic process and a subsequent etching process and the first template of parallel masking stripes has a feature dimension less than a critical dimension of the photolithographic process.

12. The method as in claim 10, wherein the second template of parallel masking stripes on the interlayer dielectric layer is formed by:
depositing the second masking material on the interlayer dielectric layer; and
applying the patterning process to pattern the second masking material into the second template of parallel masking stripes.

13. The method as in claim 1, wherein the selective removing of the magnetic element layers and the base electrode on the substrate by using the first template of parallel masking stripes as a first mask is performed by an reactive ion etching process.

14. (canceled)

15. The method as in claim 1, wherein the planar layer of the soft magnetically permeable material is formed by:
depositing the soft magnetically permeable material over the top dielectric layer to cover the magnetic elements and to substantially fill space between the magnetic elements over the substrate's surface stripes that are covered by the top dielectric layer, the method further comprising; and
applying a chemical mechanical polishing process to at least expose a top surface of the first masking material.

16. The method as in claim 15, further comprising:
forming an additional layer of a highly magnetically permeable material above or below the magnetic element layers.

17. The method as in claim 15, wherein the soft magnetic permeable material is a granular material.

18. (canceled)

19. The method as in claim 1, wherein:
the magnetic element layers of the magnetic elements are structured to exhibit a magnetization that is substantially perpendicular to the substrate.

20. The method as in claim 1, wherein:
the magnetic element layers of the magnetic elements are structured to exhibit a magnetization that is substantially parallel to and substantially lies within a plane of the substrate.

21. The method as in claim 1, wherein:
the nonmagnetic spacer layer between the fixed layer and the free layer is an electrically conducting layer so that the nonmagnetic spacer layer, the fixed layer and the free layer form a spin valve.

22. The method as in claim 1, wherein:
the nonmagnetic spacer layer between the fixed layer and the free layer is an electrically insulating layer so that the nonmagnetic spacer layer, the fixed layer and the free layer form a magnetic or magnetoresistive tunnel junction (MTJ).

23-24. (canceled)
